(19) United States
(12) Patent Application Publication
(10) Pub. No.: US 2026/0130184 A1
(43) Pub. Date: May 7, 2026

(54) DEVICE INTEGRATED WITH DEEP TRENCH ISOLATION STRUCTURE AND MANUFACTURING METHOD THEREFOR

(71) Applicant: HANGZHOU FULLSEMI SEMICONDUCTOR CO., LTD., Hangzhou (CN)

(72) Inventor: Binwei TIAN, Hangzhou (CN)

(21) Appl. No.: 19/438,208

(22) Filed: Dec. 31, 2025

(30) Foreign Application Priority Data
Jul. 31, 2025 (CN) 202511063396.9

(51) Int. Cl. H10W 10/00; H10W 10/17

(52) U.S. Cl. CPC H10W 10/014; H10W 10/17

(57) ABSTRACT

The present application relates to the field of semiconductor technologies, and in particular, to a device integrated with a deep trench isolation structure and a manufacturing method therefor. The manufacturing method may include: providing a semiconductor structure, where the semiconductor structure includes a base, a gate material layer stacked on a surface of the base, and a mask layer stacked on the gate material layer, and a functional element of a semiconductor device is formed in the base; forming a deep trench in the semiconductor structure, where the deep trench extends through the mask layer and the gate material layer, and penetrates deep into the base; filling the deep trench to form a deep trench isolation structure, where the deep trench isolation structure includes a filling structure, the filling structure is not higher than the surface of the base, and a material of the filling structure is a conductive non-metallic material; patterning and etching the gate material layer to form a gate structure; and removing the mask layer. In the present application, a manufacturing process flow of the deep trench isolation structure can be integrated into a standard process of manufacturing a gate structure of a BCD device and another device, thereby simplifying an integration process of deep trench isolation and reducing manufacturing costs.

### TECHNICAL FIELD

The present application relates to the field of semiconductor technologies, and in particular, to a device integrated with a deep trench isolation structure and a manufacturing method therefor.

### BACKGROUND

Deep trench isolation (DTI) is a critical three-dimensional isolation structure in semiconductor devices. A core function of the deep trench isolation is to implement electrical isolation between devices, making the deep trench isolation particularly suitable for device structures with high voltage, high density, and strong anti-interference requirements.

### SUMMARY

One aspect of the present application discloses a manufacturing method for a device integrated with a deep trench isolation structure, including: providing a semiconductor structure, the semiconductor structure including a base, a gate material layer stacked on a surface of the base, and a mask layer stacked on the gate material layer, and a functional element of a semiconductor device being formed in the base; forming a deep trench in the semiconductor structure, the deep trench extending through the mask layer and the gate material layer, and penetrating deep into the base; filling the deep trench to form a deep trench isolation structure, where the deep trench isolation structure includes a filling structure, and the filling structure is not higher than the surface of the base; patterning and etching the gate material layer to form a gate structure; and removing the mask layer.

In a possible implementation, after the removing the mask layer, the manufacturing method further includes: forming an isolation layer that is stacked on the surface of the base and a surface of the deep trench isolation structure and that covers the gate structure; and forming an interlayer dielectric layer on the isolation layer, and forming a metal interconnection layer based on the interlayer dielectric layer.

In a possible implementation, the forming the metal interconnection layer based on the interlayer dielectric layer includes: forming, in the interlayer dielectric layer, a plurality of contact holes extending through the interlayer dielectric layer and the isolation layer, the plurality of contact holes separately extending to the deep trench isolation structure and the gate structure; filling the plurality of contact holes with conductive materials to form a plurality of contact plug structures; and forming, above the interlayer dielectric layer, a first metal layer in contact with the contact plug structure, where the plurality of contact plug structures electrically connect the deep trench isolation structure to the first metal layer, and electrically connect the gate structure to the first metal layer.

In a possible implementation, a shallow trench isolation structure is formed in the base, and the deep trench is located at the shallow trench isolation structure and longitudinally extends through the shallow trench isolation structure.

In a possible implementation, the base has a doped buried layer located below the shallow trench isolation structure, a trench bottom of the deep trench is lower than the doped buried layer, and the deep trench and the doped buried layer are configured to isolate adjacent device modules.

In a possible implementation, the forming the deep trench in the semiconductor structure includes: forming a first blocking layer stacked on the gate material layer; performing patterning processing on the first blocking layer to expose an area of the mask layer corresponding to the deep trench; and etching the exposed area of the mask layer, an exposed area of the gate material layer, and an exposed area of the base to form the deep trench.

In a possible implementation, the filling the deep trench to form the deep trench isolation structure includes: forming an isolation oxide layer that covers a trench wall of the deep trench and that is stacked on the mask layer; etching back the isolation oxide layer to expose the trench bottom of the deep trench; forming a doped area at a bottom of the trench bottom of the deep trench; and depositing a conductive non-metallic material to obtain a filling structure filled in the deep trench, to form the deep trench isolation structure.

In a possible implementation, the depositing the conductive non-metallic material to obtain the filling structure filled in the deep trench, to form the deep trench isolation structure includes: depositing a conductive non-metallic material, to form a filling material layer filled in the deep trench and stacked on the isolation oxide layer; removing an area of the filling material layer and an area of the isolation oxide layer on the mask layer; and etching back an area of the filling material layer and an area of the isolation oxide layer in the deep trench until a remaining part of the filling material layer and a remaining part of the isolation oxide layer are not higher than the surface of the base, to form the deep trench isolation structure including the filling structure.

In a possible implementation, the conductive non-metallic material is a gate material.

In a possible implementation, the patterning and etching the gate material layer to form the gate structure includes: forming a second blocking layer, the second blocking layer blocking the surface of the deep trench isolation structure and an area of the mask layer corresponding to the gate structure; etching the mask layer to remove an area of the mask layer not blocked by the second blocking layer; and etching an area of the gate material layer exposed on the surface of the base, and removing the second blocking layer to form the gate structure.

According to another aspect, the present application further discloses a device integrated with a deep trench isolation structure, including: a base, on which a functional element of a semiconductor device is formed; a deep trench, located in the base; a deep trench isolation structure, filled in the deep trench and including a filling structure, the filling structure being not higher than a surface of the base, and a material of the filling structure being a conductive non-metallic material; and a gate structure, located on the surface of the base.

According to another aspect, the present application further discloses an integrated circuit, and the integrated circuit includes the above device integrated with a deep trench isolation structure.

According to another aspect, the present application further discloses an electronic apparatus, and the electronic apparatus includes the above device integrated with a deep trench isolation structure.

Based on the above technical solutions, the present application has the following beneficial effects:

In the technical solutions of the present application, after the gate material layer and the mask layer stacked on the gate material layer are formed on the base, etching for the deep trench and filling of the conductive non-metallic material are performed. Then, the gate material layer is patterned and etched to form the gate structure, so that the mask layer serves as a barrier layer for etching for the deep trench and manufacturing of the gate structure. Therefore, a manufacturing process flow of the deep trench isolation structure is integrated into a standard process of manufacturing the gate structure of the BCD device and another device, and there is no need to additionally introduce a mask process flow required for manufacturing the deep trench isolation structure, thereby simplifying an integration process of deep trench isolation and reducing manufacturing costs. In addition, the deep trench isolation structure is integrated into a front end of line (FEOL), so that the deep trench isolation structure can be manufactured by using existing etching and material filling processes in the FEOL, without a need to replace process tools or additionally introduce another process. In addition, the deep trench isolation structure is filled and manufactured based on the conductive non-metallic material, which has a similar thermal expansion coefficient as the base, reducing a risk of thermal expansion deformation and device damage caused by a heating process.

### BRIEF DESCRIPTION OF DRAWINGS

To describe the technical solutions in the implementations of the present application more clearly, the following briefly describes the accompanying drawings required for describing the implementations. Clearly, the accompanying drawings in the following description show merely some implementations of the present application, and a person of ordinary skill in the art can still derive other drawings from these accompanying drawings without making innovative efforts.

FIG. 1 is a schematic flowchart illustrating a manufacturing method for a device integrated with a deep trench isolation structure according to an implementation of the present application; and

FIG. 2-FIG. 15 are schematic diagrams of cross sections of a semiconductor structure in a manufacturing procedure according to an implementation of the present application.

The following supplements the accompanying drawings: 10—semiconductor structure, 100—base, 100a—substrate layer, 100b—epitaxial layer, 101—gate material layer, 102—mask layer, 103—deep trench, 104—deep trench isolation structure, 105—gate structure, 106—isolation layer, 107—shallow trench isolation structure, 108—doped buried layer, 109—first blocking layer, 110—isolation oxide layer, 111—doped area, 112—filling material layer, 113—second blocking layer, 114—pad oxide layer, 115—filling structure, 201—interlayer dielectric layer, 202—contact hole, 203—contact plug structure, 204—first metal layer.

### DESCRIPTION OF EMBODIMENTS

The following clearly and completely describes technical solutions in implementations of the present application with reference to the accompanying drawings in the implementations of the present application. It is clear that the described implementations are merely some but not all of implementations of the present application. All other implementations obtained by a person of ordinary skill in the art based on the implementations of the present application without making innovative efforts shall fall within the protection scope of the present application.

“One implementation” or “implementation” herein refers to a specific feature, structure, or feature that may be included in at least one implementation of the present application. In the description of the present application, it should be understood that an orientation or a location relationship indicated by the terms “up”, “down”, “top”, “bottom”, or the like is an orientation or a location relationship illustrated in the accompanying drawings, and is merely intended to facilitate description of the present application and simplify description, but is not intended to indicate or imply that a specified apparatus or element must have a specific orientation, be constructed in a specific orientation, or operate in a specific orientation. Therefore, this cannot be construed as a limitation on the present application. In addition, the terms “first” and “second” are used for description only, and cannot be understood as an indication or implication of relative importance or implicit indication of a number of indicated technical features. Therefore, a feature limited by “first” or “second” may explicitly or implicitly include one or more features. In addition, the terms “first”, “second”, and the like are intended to distinguish between similar objects but do not necessarily indicate a specific order or sequence. It should be understood that the data termed as such is interchangeable in proper circumstances such that the implementations of the present application described herein can be implemented in orders other than those illustrated or described herein.

When a value range is disclosed herein, the range is considered as continuous, and includes the minimum value and the maximum value of the range, and each value between the minimum value and the maximum value. Further, when a range refers to integers, each integer between the minimum value and the maximum value of the range is included. In addition, when a plurality of ranges are provided to describe features or characteristics, the ranges may be combined. In other words, unless otherwise specified, all the ranges disclosed herein shall be understood to include any and all subranges included therein. For example, a specified range from “1 to 10” should be considered to include any and all subranges between the minimum value 1 and the maximum value 10. Example subranges of the range 1 to 10 include but are not limited to 1 to 6.1, 3.5 to 7.8, 5.5 to 10, and the like.

In the present application, the term “layer” refers to a material part including an area having a thickness. The layer may extend over the entire lower or upper structure, or may extend over a local range of the lower or upper structure. In addition, the layer may be an area of a homogeneous or heterogeneous continuous structure and a thickness of the layer is less than a thickness of a continuous structure. For example, a layer may be located between a top surface and a bottom surface of the continuous structure or between any pair of horizontal planes of the continuous structure. The layer may extend horizontally, vertically, and/or along an irregular surface. The layer may include a plurality of sublayers. For example, the base 100 may include a plurality of sublayers or the like, and may have same or different materials.

It should be understood that a limitation such as “consistent”, “vertical”, or the like used in the present application refers to basically consistent, basically vertical, or the like that satisfies a process error, and does not refer to absolutely consistent or absolutely vertical in a physical sense.

It should be understood that the “surface” used in the present application, such as the “first surface”, the “second surface”, or the like, refers to an XY plane of the base 100, a substrate structure, or the like, and corresponds to an XY plane of the semiconductor structure 10. An “in-plane direction” or a “lateral direction” refers to a direction parallel to the XY plane. A “thickness direction”, a “trench depth direction”, or a “longitudinal direction” refers to a Z direction relative to the XY plane.

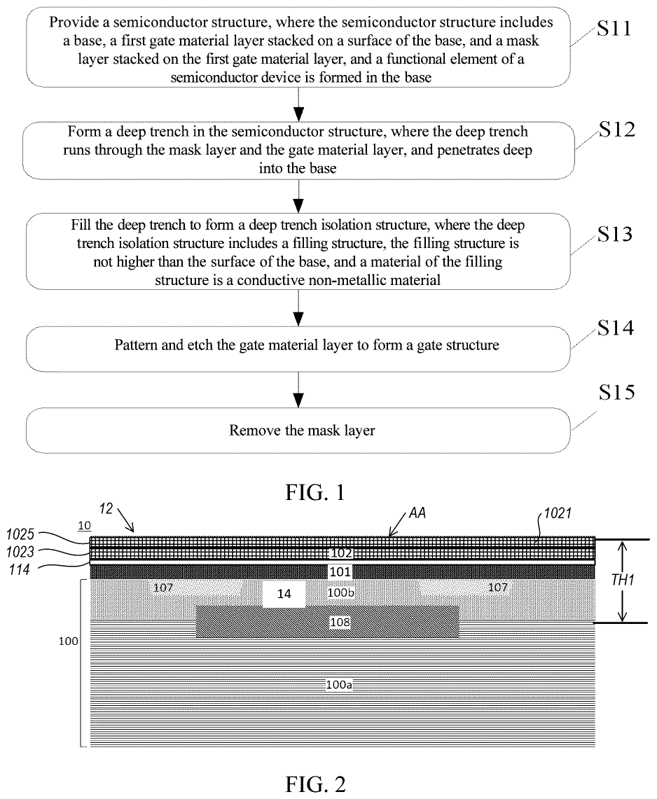

The following describes, with reference to FIG. 1-FIG. 15, a manufacturing method for a device integrated with a deep trench isolation structure 104 provided in implementations of the present application. FIG. 1 is a schematic flowchart illustrating a manufacturing method for a device integrated with a deep trench isolation structure 104. The present specification provides method operation steps as illustrated in the implementations or the flowchart, but more or fewer operation steps may be included based on convention or efforts lack of innovation. The step sequence enumerated in the implementations is only one of a plurality of step execution sequences, and does not represent a unique execution sequence. In practice, the manufacturing method may be performed sequentially or in parallel based on the method illustrated in the implementations or the accompanying drawings. The manufacturing method may include the following steps S11-S15:

S11: Receive a semiconductor structure 10.

For example, the semiconductor structure 10 includes a base 100, a gate material layer 101 stacked on a surface of the base 100, and a mask layer 102 stacked on the gate material layer 101. A functional element 14 of a semiconductor device 12 is formed in the base 100, and one or more semiconductor devices 12 may be formed in the semiconductor structure 10.

In a possible implementation, the base 100 is a semiconductor matrix capable of being processed into a semiconductor device. In some implementations, a composition material of the base 100 may be at least one of the following: silicon, a material including silicon (for example, silicon germanium SiGe or), a III-V compound semiconductor material (for example, gallium arsenide GaAs or gallium nitride GaN), silicon on insulator (SOI), or another type of semiconductor material capable of forming the base 100.

In a possible implementation, the base 100 may be a continuous structure, for example, may be a wafer substrate, or may include a substrate layer 100a and an epitaxial layer 100b. In some implementations, the epitaxial layer 100b may be, for example, formed by using an epitaxial growth process, or the epitaxial layer 100b may be homogeneous with the substrate layer 100a, for example, continuous growing may be performed along a lattice direction of the substrate layer 100a to form the epitaxial layer 100b. Alternatively or additionally, the epitaxial layer 100b may be heterogeneous. A process condition such as a growth temperature may be the same as that in an existing process, or may be adjusted adaptively. In some implementations, the epitaxial layer 100b may be formed by using chemical vapor deposition (CVD), physical vapor deposition (PVD), atomic layer deposition (ALD), or another method. For example, a material of the epitaxial layer 100b may include silicon, germanium, gallium arsenide, gallium phosphide (GaP), gallium nitride (GaN), or the like, or may be another material that is capable of epitaxially growing or being deposited on the substrate layer 100a and capable of being processed in a device area. In a possible implementation, referring to FIG. 2, the functional element 14 of the semiconductor device 12 in the base 100 is located in the epitaxial layer 100b.

For example, the functional element 14 in the base 100 may be manufactured and disposed based on a requirement of the semiconductor device, for example, may be a functional element in an active area of a power transistor device (for example, a shielded gate trench metal oxide semiconductor field effect transistor (SGT MOSFET)), for example, a shielded gate trench structure, or may be a metal oxide semiconductor (MOS) transistor unit of a bipolar-complementary metal oxide semiconductor-high-voltage power field effect transistor (Bipolar CMOS DMOS) device. It may be understood that the semiconductor device may be a radio frequency (RF) device, or the like.

For example, the gate material layer 101 is a continuous film layer of a gate structure 105, and is formed by depositing a gate material. The gate material may be various conductive materials, which include but are not limited to polysilicon, metal materials, conductive compounds like TiN, or the like. In some implementations, a deposition process may be implemented by using a process such as chemical vapor deposition (CVD), for example, plasma enhanced chemical vapor deposition (PECVD), high-density plasma chemical vapor deposition (HDPECVD), sub-atmospheric chemical vapor deposition (SACVD), low pressure chemical vapor deposition (LPCVD), atomic layer deposition (ALD), plasma enhanced atomic layer deposition (PEALD), or another type of chemical vapor deposition process.

For example, referring to FIG. 2, the mask layer 102 covers at least an active area (AA) of the semiconductor device. In some implementations, the mask layer 102 includes a hard mask layer 1021, which serves as a patterned transfer layer during subsequent manufacturing of the gate structure 105, is used for pattern transfer and improving precision of patterning and etching, and may be formed by using a deposition process. In some implementations, a material of the hard mask layer may include at least one of silicon nitride, titanium nitride, silicon oxynitride, silicon dioxide, or the like, or may be another material capable of implementing pattern transfer. In some other implementations, the mask layer 102 may further include a pad oxide layer 114, and the pad oxide layer 114 is located between the hard mask layer 1021 and the gate material layer 101, and is configured to isolate and protect a surface of the gate material layer 101, to avoid surface contamination and reduce stress of the hard mask layer. A pad oxide may be formed on the gate material layer 101 by using a thermal oxidation or deposition process. In some implementations, a material of the pad oxide layer 114 may include but is not limited to silicon dioxide or the like.

In an implementation, the hard mask layer 1021 of the mask layer 102 includes a first sublayer 1023 stacked on the gate material layer 101 and a second sublayer 1025 stacked on the first sublayer. Materials of the first sublayer 1023 and the second sublayer 1025 may be the same or different. A deposition density of the second sublayer 1025 is higher than a deposition density of the first sublayer 1023, which helps to increase surface compactness of the mask layer 102, thereby increasing surface flatness and reducing a surface defect, further optimizing a manufacturing process of a deep trench isolation structure 104 and the gate structure 105, and improving a device effect. In some implementations, a thickness of the second sublayer is less than a thickness of the first sublayer. For example, the thickness of the first sublayer is 2500-2800 A, e.g., 2700 A. The thickness of the second sublayer is 300-350 A, e.g., 320 A. A material of the hard mask layer may be silicon oxynitride.

In some implementations, a thickness TH1 from a top surface of the substrate layer 100a to a top surface of the mask layer 102 is 8-12 μm.

S12: Form a deep trench 103 in the semiconductor structure 10.

For example, the deep trench 103 extends through the mask layer 102 and the gate material layer 101, and penetrates deep into the base 100. The deep trench 103 is configured to isolate a device module of a device integrated with the deep trench isolation structure, and the device module may include some functional modules in the semiconductor device, or may be a complete semiconductor device.

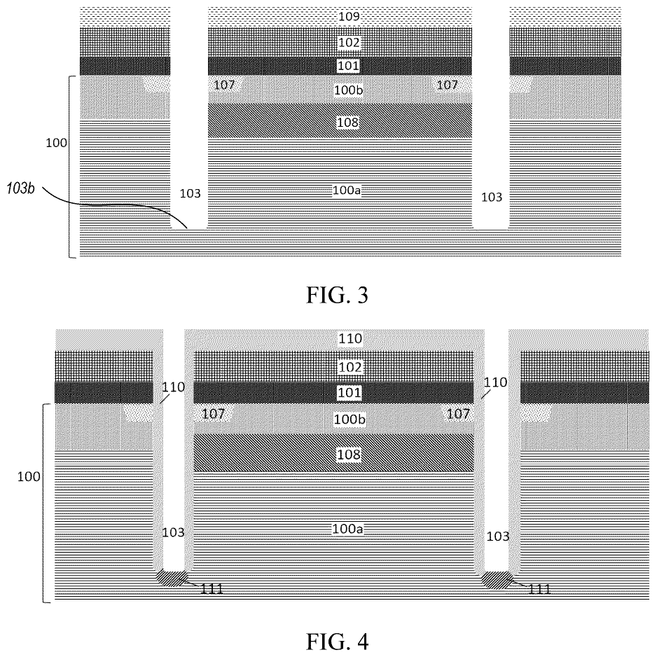

For example, referring to FIG. 3, the deep trench 103 may be formed based on a patterning and etching process. In a possible implementation, that form the deep trench 103 in the semiconductor structure 10 in S12 may include S121-S123.

S121: Form a first blocking layer 109 stacked on the gate material layer 101.

S122: Perform patterning processing on the first blocking layer 109 to expose an area of the mask layer 102 corresponding to the deep trench 103.

S123: Etch the exposed area of the mask layer 102, an exposed area of the gate material layer, and an exposed area of the base 100 to form the deep trench 103.

For example, a photoresist may be coated on the mask layer 102, to cover the first blocking layer 109 of the mask layer 102. Patterned exposure processing is performed on the first blocking layer 109. An area of the mask layer 102 on which deep trench etching needs to be performed is exposed by using the patterned first blocking layer 109. Etching processing is performed on the mask layer 102 by using the first blocking layer 109 as an etching barrier layer, to form an etching window. Then, the gate material layer 101 and an underlying base structure exposed by the etching window are etched to obtain the deep trench 103. The deep trench may be etched by using a wet etching process, for example, phosphoric acid may be used as an etching solution of wet etching, or by using a dry etching process, including but not limited to at least one of ion milling etching, plasma etching, reactive ion etching, or laser ablation. For example, plasma etching and the like may be performed by using a mixed gas of C₄F₈ and O₂.

In some implementations, a shallow trench isolation structure 107 is formed in the base 100, and the deep trench 103 is formed to overlap or within the shallow trench isolation structure 107 and to vertically extend through the shallow trench isolation structure 107.

For example, a location of the deep trench 103 is within the shallow trench isolation structure 107. In some implementations, referring to FIG. 3, a width of the shallow trench isolation structure 107 is greater than that of the deep trench 103. The deep trench 103 vertically extends through the shallow trench isolation structure 107 and the epitaxial layer 100b, and then a layer of the base 100, to implement effective isolation. As such, first level isolation is performed with reference to the shallow trench isolation structure 107 in a standard device. In addition, the deep trench isolation structure 104 is further integrated at a location that requires high voltage resistance or high electrical isolation, which facilitates positioning of the deep trench 103 and significantly improves device performance.

In some implementations, referring to FIG. 2, the base 100 has a doped buried layer 108 located below the shallow trench isolation structure 107, the deep trench 103 extends downwardly beyond the doped buried layer 108, and a trench bottom of the deep trench 103 is lower than the doped buried layer 108, and the deep trench 103 and the doped buried layer 108 are configured to isolate adjacent device modules, thereby avoiding a crosstalk problem of adjacent functional modules or adjacent semiconductor devices.

In some implementations, referring to FIG. 12, the deep trench isolation structure 104 abuts against the doped buried layer 108.

For example, based on a device requirement, the doped buried layer 108 may be an N-type buried layer (NBL) or a P-type buried layer (PBL), to reduce an N-region resistance for longitudinal isolation, or reduce a P-region resistance for optimizing substrate biasing. The doped buried layer 108 is located between the substrate and the epitaxial layer 100b, and may be formed through ion implantation and high temperature annealing.

S13: Fill the deep trench 103 to form the deep trench isolation structure 104.

For example, the deep trench isolation structure includes a filling structure 115, the filling structure 115 is not higher than the surface of the base, and a material of the filling structure 115 is a conductive non-metallic material, thereby avoiding electric leakage and facilitating planarization of a device surface, reducing a difference between stress of the deep trench isolation structure and the base, and avoiding a risk of cracking and deformation of the deep trench isolation structure.

For example, the first blocking layer 109 is removed, to expose the mask layer 102. After an isolation material layer 110 is formed on a trench wall of the deep trench 103, a conductive non-metallic material, e.g., similar to that of the gate material layer 101, is filled to obtain the deep trench isolation structure 104. In some implementations, the isolation material layer 110 may be an isolation oxide layer 110. Isolation between the conductive non-metallic material of the filling structure 115 and a base material of the substrate 110a is implemented by using the isolation oxide layer 110, to avoid diffusion of the conductive non-metallic material caused by a high-temperature procedure. In some implementations, the deep trench 103 is filled with the gate material of the gate material layer 101, so that prior deposition process flows of the gate material layer 101 can be integrated without a need to switch process tools, thereby significantly reducing process complexity. It should be appreciated that the filling structure 115 may be formed with other conductive materials different from the gate material layer 101, which is also included in the scope of the application.

In a possible implementation, referring to FIG. 4-FIG. 8, S13, the filling the deep trench 103 to form the deep trench isolation structure 104 may include S131-S134.

S131: Form an isolation oxide layer 110 that covers the trench wall of the deep trench 103 and that is stacked on the mask layer 102.

S132: Etch back the isolation oxide layer 110 to expose the trench bottom of the deep trench 103.

S133: Form a doped area 111 through or at a bottom 103b of the trench bottom of the deep trench 103.

S134: Deposit a conductive non-metallic material to obtain a filling structure 115 filled in the deep trench 103, to form the deep trench isolation structure 104.

For example, the isolation oxide layer 110 may be formed based on a thermal oxidation process or a deposition process. In some implementations, referring to FIG. 4, an oxide material is deposited by using the deposition process to form the isolation oxide layer 110 that covers the trench wall of the deep trench 103 and that is stacked on the mask layer 102. Then, the isolation oxide layer 110 is etched back to remove at least a part area of the isolation oxide layer at the trench bottom of the deep trench 103 and retain an area of the isolation oxide layer at a sidewall of the deep trench 103. Next, ion implantation is performed on the trench bottom of the deep trench 103 to form the doped area 111. Etch-back processing herein may be implemented through wet etching or dry etching. The doped area may be used as a ground electrode, to improve an isolation effect of the deep trench isolation structure 104. In addition, after the isolation oxide layer 110 is formed, an ion implantation process flow of trench bottom doping is performed, which can effectively protect a base structure of the trench wall of the deep trench, and facilitate full contact between the conductive non-metallic material subsequently filled and the doped area 111. In some implementations, a thickness of the isolation oxide layer 110 may be 500-1200 A.

In some implementations, the doped area 111 may be formed by using a rapid thermal annealing (RTA) process, and diffusion of the doped area is implemented through instantaneous high temperature processing (for example, 1000-1100° C., for several seconds to dozens of seconds), thereby improving device performance.

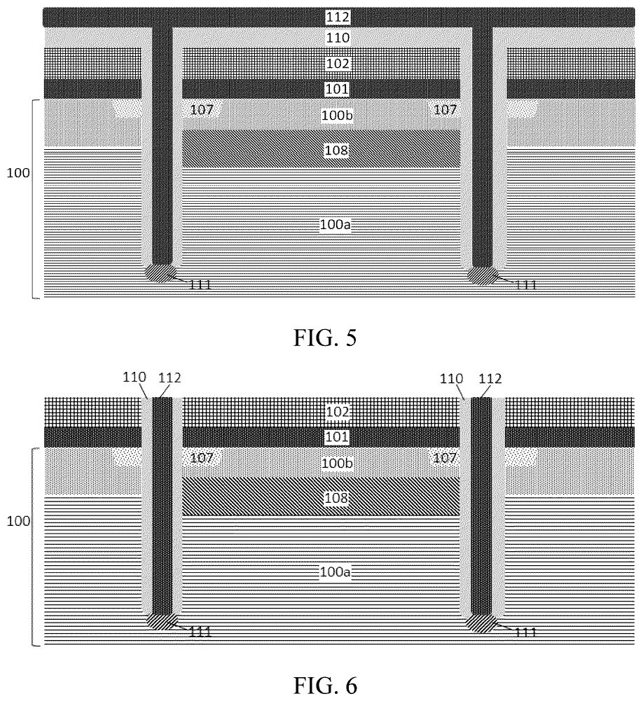

In a possible implementation, referring to FIG. 5-FIG. 8, the depositing the conductive non-metallic material to obtain the filling structure 115 filled in the deep trench 103, to form the deep trench isolation structure 104 in S134 may include: depositing the conductive non-metallic material, to form a filling material layer 112 filled in the deep trench 103 and stacked on the isolation oxide layer 110; removing a portion of the filling material layer and a portion of the isolation oxide layer on the mask layer 102; and etching back a portion of the filling material layer and a portion of the isolation oxide layer in the deep trench 103, until a remaining part of the filling material layer 112 and a remaining part of the isolation oxide layer 110 are not higher than the surface 100s of the base 100, to form the deep trench isolation structure 104 including the filling structure 115.

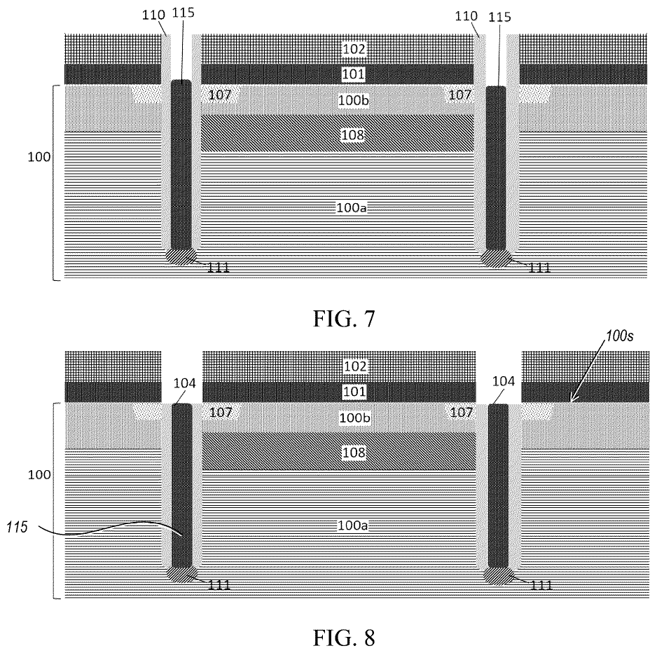

For example, referring to FIG. 5-FIG. 6, chemical mechanical polishing (CMP) processing may be performed on the filling material layer 112, to remove the conductive non-metallic material covering the isolation oxide layer 110. Then, CMP processing is performed on the isolation oxide layer 110 by using the mask layer 102 as a stop layer, until the portion of the filling material layer and the portion of the isolation oxide layer stacked on the mask layer 102 are removed. Referring to FIG. 7-FIG. 8, the conductive non-metallic material and the isolation oxide layer in the deep trench 103 are etched back using wet etching or dry etching, a remaining part of the filling material layer 112 after the etching back forms the filling structure 115, and the filling structure 115 is on a same level, e.g., coplanar, with the surface 100s of the base 100 or lower than the surface 100s of the base 100. For example, the conductive non-metallic material may be a gate material, which may, for example, include but is not limited to polysilicon or the like. In some implementations, a thickness of an area of the filling material layer 112 stacked on the isolation oxide layer 110 is 0.8-1.3 μm.

Referring to FIG. 8, the deep trench isolation structure 104 may include the doped area 111 located at a bottom of the deep trench 103, the isolation oxide layer 110 located at the sidewall of the deep trench 103, and the filling structure 115 in the deep trench 103, to form a structure capable of being grounded, thereby improving a device isolation effect and voltage withstanding performance.

S14: Pattern and etch the gate material layer 101 to form a gate structure 105.

For example, after the deep trench isolation structure 104 is formed, the gate material layer 101 is patterned and etched by using the mask layer 102 as a pattern transfer layer, to obtain the gate structure 105.

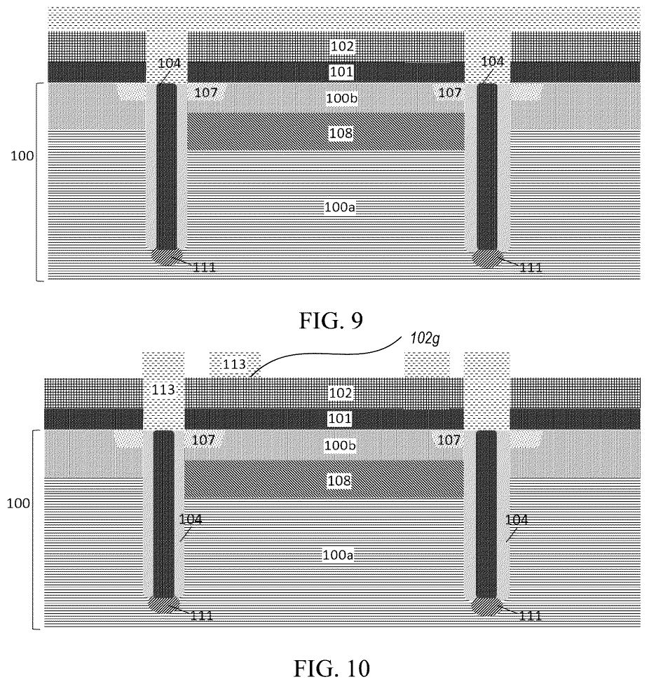

In a possible implementation, referring to FIG. 9-FIG. 12, the patterning and etching the gate material layer 101 to form the gate structure 105 in S14 may include S141-S143.

S141: Form and pattern a second blocking layer 113, where the second blocking layer 113 blocks a surface of the deep trench isolation structure 104 and an area 102g of the mask layer 102 corresponding to the gate structure 105.

S142: Etch the mask layer 102 to remove portions of the mask layer 102 not blocked by the second blocking layer 113.

S143: Etch portions of the gate material layer exposed from the mask layer 102, and remove the second blocking layer 113 to form the gate structure 105.

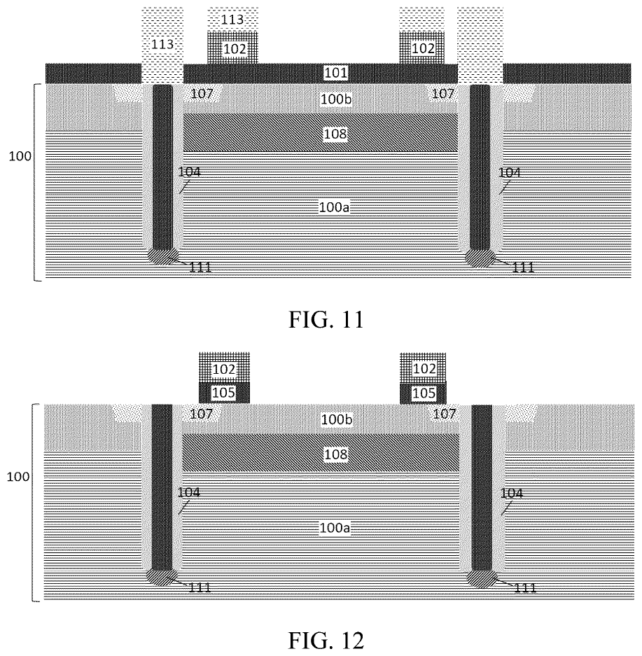

For example, referring to FIG. 9, a photoresist 113 may be coated on the mask layer 102, so that the mask layer 102 is blocked and the deep trench isolation structure 104 is blocked. Then, patterned exposure processing is performed on the photoresist, referring to FIG. 10, to expose the mask layer 102 that corresponds to a portion of the gate material layer that needs to be removed, thereby obtaining the second blocking layer 113 that blocks the surface of the deep trench isolation structure 104 and a portion of the mask layer 102 corresponding to the gate structure 105. Referring to FIG. 11, the exposed mask layer 102 is etched to form an etching window. Next, an area of the gate material layer exposed by the etching window is patterned and etched. Then, the second blocking layer 113 is removed, and a remaining area of the gate material layer forms the gate structure 105, as illustrated in FIG. 12. As such, manufacturing of the deep trench isolation structure 104 and the gate structure 105 is implemented by using the same mask layer 102, thereby simplifying a manufacturing process of integrating the deep trench isolation structure 104 into the semiconductor device.

S15: Remove the mask layer 102.

For example, after the gate structure 105 is manufactured, the mask layer 102 is removed, to enter a back end of line (BEOL) process of the semiconductor device manufacturing.

In conclusion, in this implementation, after the gate material layer 101 and the mask layer 102 stacked on the gate material layer 101 are formed on the base 100, etching for the deep trench and filling of the conductive non-metallic material are performed. Then, the gate material layer 101 is patterned and etched to form the gate structure 105, so that the mask layer 102 serves as a barrier layer for etching for the deep trench and manufacturing of the gate structure 105. Therefore, a manufacturing process flow of the deep trench isolation structure 104 is integrated into a standard process of manufacturing the gate structure 105 of the BCD device and another device, and there is no need to additionally introduce a mask process flow required for manufacturing the deep trench isolation structure 104, thereby simplifying an integration process of deep trench 103 isolation and reducing manufacturing costs. In addition, the deep trench isolation structure 104 is integrated into a front end of line (FEOL), so that the deep trench isolation structure 104 can be manufactured by using existing etching and material filling processes in the FEOL, without a need to replace process tools or additionally introduce another process. In addition, the deep trench isolation structure 104 is filled and manufactured based on the conductive non-metallic material, which has a similar thermal expansion coefficient as the base 100, reducing a risk of thermal expansion deformation and device damage caused by a heating process.

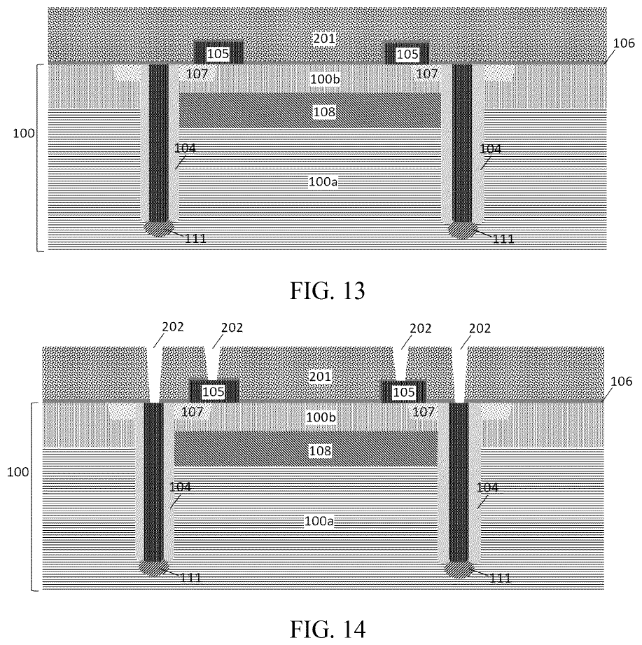

Based on the above some or all implementations, in a possible implementation, after the mask layer 102 is removed in S15, referring to FIG. 13-FIG. 15, the manufacturing method further includes S16-S17.

S16: Form an isolation layer 106 on the surface of the base 100 and the surface of the deep trench isolation structure 104 and covering the gate structure 105.

S17: Form an interlayer dielectric layer 201 on the isolation layer 106, and form a metal interconnection layer in the interlayer dielectric layer 201.

For example, the isolation layer 106 may be formed using a deposition process, and the isolation layer 106 serves as a dielectric layer for electrical isolation. In some implementations, a material of the dielectric layer 106 may include one or more of silicon dioxide, silicon nitride, silicon oxynitride, hafnium oxide, zirconium oxide, and the like, or may be another material capable of being used as the dielectric layer. After the isolation layer 106 is formed, the interlayer dielectric (ILD) layer 201 is formed on the isolation layer 106. In some implementations, a material of the interlayer dielectric layer 201 may include one or more of silicon dioxide, fluorinated silicate glass (FSG), boron phosphosilicate glass (BPSG), and a carbon-doped oxide (for example, SiCOH), or may be another material capable of being used as the interlayer dielectric layer 201.

In a possible implementation, the forming the metal interconnection layer based on the interlayer dielectric layer 201 in S17 may include S171-S173.

S171: Form, in the interlayer dielectric layer 201, a plurality of contact holes 202 extending through the interlayer dielectric layer 201 and the isolation layer 106.

S172: Fill the plurality of contact holes 202 with conductive materials to form a plurality of contact plug structures 203.

S173: Form, above the interlayer dielectric layer 201, a first metal layer 204 in contact with the contact plug structure 203.

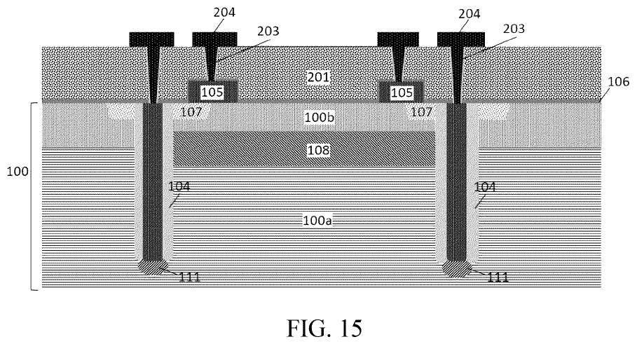

For example, referring to FIG. 14, a via pattern may be defined by using photolithography, and then the interlayer dielectric layer 201 and the isolation layer 106 are etched to form the contact hole 202. The plurality of contact holes 202 separately extend to the deep trench isolation structure 104 and the gate structure 105, to expose areas of the deep trench isolation structure 104 and the gate structure 105 that need to be electrically connected. Then, the conductive material is used for filling to form the contact plug structure 203 as an interconnection structure. Then, referring to FIG. 15, a first metal layer 204 is formed, to be electrically connected to the contact plug structure 203. For example, the plurality of contact plug structures 203 electrically connect the deep trench isolation structure 104 to the first metal layer 204, and electrically connect the gate structure 105 to the first metal layer 204. It may be understood that after the first metal layer 204 is manufactured, an intermetal dielectric (IMD) layer and a second metal layer may be further manufactured, to complete manufacturing of the metal interconnection layer. In this implementation, manufacturing of the deep trench isolation structure 104 is integrated into the FEOL, thereby being capable of adapting to various BEOL processes, for example, being capable of adapting to a metal-layer manufacturing process such as a conventional sputtering and etching process (for example, an aluminum-based process) and a damascene process (for example, a copper based process).

In conclusion, in the technical solution of the present application, after a manufacturing process flow of DTI is integrated into a deposition process flow of the mask layer of the gate material layer, the DTI is formed in the front-end-of-line FEOL process of the device, to avoid a problem of a relatively high thickness of the IMD or ILD layer caused by integrating manufacturing of the DTI into the BEOL, thereby avoiding affecting procedures such as contact hole etching (CT-ET) and via etching. In addition, the mask layer further serves as the hard mask layer for etching for the trench in the DTI and manufacturing of the gate structure, and the DTI is formed by filling of the conductive non-metallic material, so that manufacturing of the DTI is integrated into a standard process of the FEOL of the device, thereby reducing difficulty of CMP of the DTI, and simplifying a process flow while ensuring an improvement in a device effect. In addition, the doped area formed by using the ion implantation is introduced in the DTI structure, thereby improving an isolation effect.

An implementation of the present application further provides a device integrated with the deep trench isolation structure 104, which is manufactured based on the above manufacturing method. Referring to FIG. 12, the device integrated with the deep trench isolation structure 104 for example includes: a base 100, a deep trench 103, a deep trench isolation structure 104, and a gate structure 105. A functional element of a semiconductor device is formed in the base 100. The deep trench 103 is located in the base 100. The deep trench 103 is filled with the deep trench isolation structure 104, which includes a filling structure 115, the filling structure 115 is not higher than a surface of the base 100, and a material of the filling structure 115 is a conductive non-metallic material. The gate structure 105 is located on the surface of the base 100.

In a possible implementation, referring to FIG. 13, the device further includes an isolation layer 106 that is stacked on the surface of the base 100 and a surface of the deep trench isolation structure 104 and that covers the gate structure 105; and a metal interconnection layer stacked on the isolation layer 106.

In some implementations, referring to FIG. 15, an interlayer dielectric layer 201 includes a plurality of contact holes 202 extending through the interlayer dielectric layer 201 and the isolation layer 106. The metal interconnection layer includes a plurality of contact plug structures 203 and a first metal layer 204. The plurality of contact plug structures 203 electrically connect the deep trench isolation structure 104 to the first metal layer 204, and electrically connect the gate structure 105 to the first metal layer 204.

In some implementations, referring to FIG. 12-FIG. 15, a shallow trench isolation structure 107 is formed in the base 100, and the deep trench 103 overlaps the shallow trench isolation structure 107 and longitudinally extends through the shallow trench isolation structure 107.

In some implementations, referring to FIG. 12-FIG. 15, the base 100 has a doped buried layer 108 located below the shallow trench isolation structure 107, a trench bottom of the deep trench 103 is lower than the doped buried layer 108, and the deep trench 103 and the doped buried layer 108 are configured to isolate adjacent device modules.

It should be noted that the implementations of the device integrated with a deep trench isolation structure in the present application are implemented based on the implementations of the manufacturing method of a device integrated with a deep trench isolation structure, and the two are based on a same invention concept.

An implementation of the present application further provides an electronic device, and the electronic device includes the above semiconductor structure 10. For example, the electronic device includes the semiconductor structure 10 and an electronic assembly connected to the above semiconductor structure 10.

The electronic device in this implementation of the present application may be selected from any electronic product or device such as a mobile phone, a personal digital assistant (PDA), a tablet computer (pad), a notebook computer, a game console, a television set, a video compact disc (VCD), a digital video disc (DVD), a navigator, a camera, a video camera, a recording pen, an MP3, an MP4, a playstation portable (PSP), or the like, or may be any intermediate product including an electronic device manufactured by the above semiconductor structure 10.

It should be noted that the above sequence of the implementations of the present application is merely for the purpose of description, and is not intended to indicate priorities of the implementations. In addition, the above describes a specific implementation of the present specification. Other implementations are within the scope of the appended claims. In some cases, the actions or steps described in the claims may be performed in a different sequence than in the implementations and may still achieve the desired results. In addition, the procedure depicted in the accompanying drawings does not necessarily require a particular sequence or consecutive sequence illustrated to achieve the desired results. In some implementations, multitasking and parallel processing are also possible or may be advantageous.

Implementations of the present specification are described in a progressive manner, and for the same and similar parts of implementations, references can be made to each other. Each implementation focuses on a difference from other implementations. In particular, for the device implementation, because the device implementation is basically similar to the method implementation, description is relatively simple. For related parts, references can be made to parts of the method implementation descriptions.

A person of ordinary skill in the art may understand that all or some of the steps of the implementations may be implemented by hardware, or may be implemented by a program instructing related hardware. The program of the implementations may be stored in a computer-readable storage medium. The above storage medium may be a read-only memory, a magnetic disk, an optical disc, or the like.

The above descriptions are merely example implementations of the present application, and are not used to limit the present application. Any modification, equivalent replacement, or improvement made in the spirit and principle of the present application shall fall within the protection scope of the present application.

1. A manufacturing method for a device integrated with a deep trench isolation structure, comprising:
receiving a semiconductor structure, the semiconductor structure including a base, a gate material layer on a surface of the base, and a mask layer on the gate material layer, the base including a functional element of a semiconductor device in the base;
forming a deep trench in the semiconductor structure, the deep trench extending through the mask layer and the gate material layer, and extending into the base;
forming a deep trench isolation structure including a filling structure in the deep trench, the filling structure being not higher than the surface of the base, and the filling structure including a conductive non-metallic material; and
patterning the gate material layer to form a gate structure; and
removing the mask layer.

2. The manufacturing method according to claim 1, further comprising:
after the removing the mask layer,
forming an isolation layer on the surface of the base and a surface of the deep trench isolation structure, the isolation layer covering the gate structure;
forming an interlayer dielectric layer on the isolation layer; and
forming a metal interconnection layer at least partially in the interlayer dielectric layer.

3. The manufacturing method according to claim 2, wherein the forming the metal interconnection layer at least partially in the interlayer dielectric layer includes:
forming, in the interlayer dielectric layer, a plurality of contact holes extending through the interlayer dielectric layer and the isolation layer, the plurality of contact holes separately extending to the deep trench isolation structure or the gate structure, respectively;
filling the plurality of contact holes with a conductive material to form a plurality of contact plug structures; and
forming, on the interlayer dielectric layer, a first metal layer in contact with the contact plug structure, wherein the plurality of contact plug structures are in contact with the deep trench isolation structure and the first metal layer, or in contact with the gate structure and the first metal layer.

4. The manufacturing method according to claim 1, comprising forming a shallow trench isolation structure in the base, wherein the forming the deep trench includes forming the deep trench that overlaps the shallow trench isolation structure and vertically extends through the shallow trench isolation structure.

5. The manufacturing method according to claim 4, wherein the base has a doped buried layer located below the shallow trench isolation structure, a trench bottom of the deep trench is lower than the doped buried layer.

6. The manufacturing method according to claim 1, wherein the forming the deep trench in the semiconductor structure includes:
forming a first blocking layer on the gate material layer;
patterning the first blocking layer to expose an area of the mask layer corresponding to the deep trench; and
etching the exposed area of the mask layer, an exposed area of the gate material layer, and an exposed area of the base to form the deep trench.

7. The manufacturing method according to claim 1, wherein the forming the deep trench isolation structure includes:
forming an isolation oxide layer on a trench wall of the deep trench and on the mask layer;
etching the isolation oxide layer to expose a trench bottom of the deep trench;
forming a doped area through the trench bottom of the deep trench; and
depositing the conductive non-metallic material in the deep trench to form the filling structure in the deep trench.

8. The manufacturing method according to claim 7, wherein the depositing the conductive non-metallic material to form the filling structure in the deep trench includes:
depositing the conductive non-metallic material, to form a filling material layer filled in the deep trench and on the isolation oxide layer;
removing a portion of the filling material layer and a portion of the isolation oxide layer on the mask layer; and
etching a portion of the filling material layer and a portion of the isolation oxide layer in the deep trench until a remaining portion of the filling material layer and a remaining portion of the isolation oxide layer are not higher than the surface of the base.

9. The manufacturing method according to claim 1, wherein the patterning the gate material layer includes:
forming a second blocking layer on a surface of the deep trench isolation structure and a first portion of the mask layer corresponding to the gate structure;
etching the mask layer to remove a second portion of the mask layer not blocked by the second blocking layer; and
etching a portion of the gate material layer exposed from the mask layer, and removing the second blocking layer to form the gate structure.

10. A device integrated with a deep trench isolation structure, comprising:
a base, the base including a functional element of a semiconductor device;
a deep trench, located in the base;
a deep trench isolation structure in the deep trench, the deep trench isolation structure including a filling structure having a conductive non-metallic material, the filling structure being not higher than a surface of the base; and
a gate structure, located on the surface of the base.
